(19) United States
(12) Patent Application Publication
(10) Pub. No.: US 2004/0238370 A1
(43) Pub. Date: Dec. 2, 2004

(54) PRINTED CIRCUIT BOARD MANUFACTURING METHOD

(75) Inventors: Ryoichi Watanabe, Yamashina (JP); Tatsuji Yamada, Shiga (JP); Shogo Mizumoto, Otsu-city (JP); Fumio Kumokawa, Osaka-fu (JP)

Correspondence Address: IBM MICROELECTRONICS, INTELLECTUAL PROPERTY LAW, 1000 RIVER STREET, 972 E, ESSEX JUNCTION, VT, 05452, US

(73) Assignee: INTERNATIONAL BUSINESS MACHINES CORPORATION, Armonk, NY (US)

(21) Appl. No.: 10/709,474

(22) Filed: May 7, 2004

(30) Foreign Application Priority Data
May 8, 2003 (JP) 2003-129874

(51) Int. Cl. H05K 3/00; C25D 5/02; C25D 5/48; H01L 21/44

(52) U.S. Cl. 205/125; 205/223; 438/674; 438/678; 438/687

(57) ABSTRACT

A method of manufacturing a printed circuit board is disclosed. A seed layer is removed while etching of a circuit pattern is prevented. In a printed circuit board manufacturing process according to a semi-additive method, a seed layer is formed by electroless copper plating. Using a resist pattern, a circuit pattern is formed by electrolytic copper plating. After the formation of the circuit pattern, the exposed regions of seed layer are subjected to etching. According to the invention, an etching liquid at a temperature of about 15° C. or less is used. As a temperature of the etching liquid is lowered, a potential difference between the seed layer and the circuit pattern increases. Due to the increase in potential difference, the seed layer becomes more susceptible to being etched, while the circuit pattern becomes less susceptible to being etched.

### BACKGROUND OF INVENTION

1. Field of the Invention

The present invention relates to a method of manufacturing a printed circuit board and, more specifically, relates to a method of manufacturing a printed circuit board using a semi-additive method.

2. Background of the Invention

In a semi-additive method of manufacturing a high-density printed circuit board, a seed layer is first formed on a substrate serving as an insulating layer by electroless copper plating. The seed layer is formed by an electroless copper plating layer. Thereafter, a resist pattern is formed on the seed layer by photolithography. Using the formed resist pattern, a circuit pattern is formed by electrolytic copper plating. The circuit pattern is formed by an electrolytic copper plating layer. After the formation of the circuit pattern, the resist pattern is removed. The seed layer formed under the removed resist pattern is removed by etching (hereinafter, this etching will be referred to as “flash etching”). During the flash etching, an SPS (sodium persulfate) aqueous solution, for example, is used as an etching liquid.

Inasmuch as the seed layer and the circuit pattern are both formed by copper plating, not only the seed layer but also the circuit pattern is etched during the flash etching.

Further, the corners of the circuit pattern are rounded off by the flash etching, so it becomes difficult to control a pad width that is required upon mounting. Therefore, in the semi-additive method, it is important to prevent the etching of the circuit pattern during the flash etching.

On the other hand, in terms of reducing a manufacturing time, a shorter etching time is desirable. FIG. 4 shows the relationship between a breakpoint and a temperature of an etching liquid with respect to a substrate formed thereon with only a seed layer. The breakpoint represents a time until the unnecessary seed layer is fully removed by the flash etching. In FIG. 4, since the substrate formed thereon with only the seed layer is used, the breakpoint represents a time until the seed layer on the substrate is fully removed. As is seen from FIG. 4, as the temperature of the etching liquid rises, the breakpoint is reduced.

Even when a circuit pattern is formed on the seed layer, the breakpoint is assumed to be reduced as the temperature of the etching liquid rises. However, as the temperature of the etching liquid is increased, the circuit pattern becomes more susceptible to being etched.

### SUMMARY OF INVENTION

An aspect of the invention is to provide a method of manufacturing a printed circuit board which can etch a seed layer while preventing etching of a circuit pattern.

Another aspect of the invention is to provide a method of manufacturing a printed circuit board which can reduce a process time.

A method of forming a printed circuit board according to the invention comprises the steps of providing a substrate comprising a seed layer formed by electroless plating;

forming a masking layer on said seed layer to provide first regions of exposed seed layer; forming a circuit pattern on said first regions of exposed seed layer by electrolytic plating; removing said masking layer to expose second regions of said seed layer; and etching said exposed second regions of said seed layer with an etching liquid, said etching liquid at a temperature less than about 15 degrees Celcius.

In a printed circuit board manufacturing method according to the invention, the etching liquid is at a lower temperature than room temperature (i.e. about 20 degrees Celcius). Since the seed layer is formed by the electroless plating while the circuit pattern is formed by the electrolytic plating, the circuit pattern becomes a more noble metal than the seed layer, and conversely, the seed layer becomes a more base metal than the circuit pattern. Therefore, a potential of the circuit pattern becomes higher than that of the seed layer. A potential difference caused therebetween increases as the temperature of the etching liquid decreases. Therefore, as the temperature of the etching liquid decreases, the seed layer becomes more susceptible to being etched, while the circuit pattern becomes more resistant to being etched relative to the seed layer. Inasmuch as the seed layer becomes more susceptible to being etched as the temperature of the etching liquid is decreased as described above, an etching time is shortened and, as a result, a manufacturing time of a printed circuit board can be reduced. When the etching time is reduced, an amount of the circuit pattern that is etched can be reduced.

### BRIEF DESCRIPTION OF DRAWINGS

FIGS. 1(a) to 1(e) illustrate a method of manufacturing a printed circuit board according to an embodiment of the invention;

FIG. 2 illustrates a relationship between a potential difference of a seed layer (electroless plating layer) relative to a circuit pattern (electrolytic plating layer), and a temperature of an etching liquid in an etching process shown in FIG. 1(d);

FIG. 3 illustrates a relationship between temperature variation of an etching liquid and a breakpoint in flash etching according to an embodiment of the invention; and

FIG. 4 illustrates a relationship between a breakpoint and a temperature of an etching liquid with respect to only a seed layer formed on a substrate.

### DETAILED DESCRIPTION

An embodiment of the invention will be described in detail with reference to the drawings. In the drawings, the same or corresponding portions are assigned the same reference symbols to thereby incorporate the description thereof.

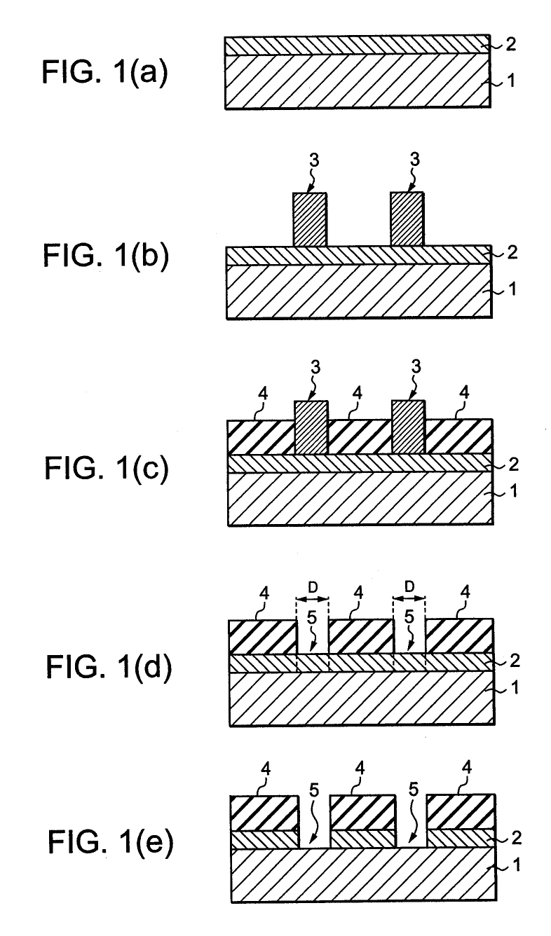

Referring to FIGS. 1(a) to 1(e), in a method of manufacturing a printed circuit board according to a semi-additive method, a seed layer 2 is formed on a substrate 1 by electroless copper plating (see FIG. 1(a)). The seed layer 2 is formed by an electroless copper plating layer. After forming the seed layer 2 on the substrate 1, a resist pattern 3 is formed on the seed layer 2 by photolithography as shown in FIG. 1(b). Referring to FIG. 1(c), resist pattern 3 is formed, then a circuit pattern 4 is formed by electrolytic copper plating in regions in the resist pattern 3 where no resist is formed (i.e. regions where the seed layer 2 is exposed). The circuit pattern 4 is formed by an electrolytic copper plating layer. After the formation of the circuit pattern 4, the resist pattern 3 is removed as shown in FIG. 1(d). The seed layer 2 is exposed in regions 5 where the resist pattern 3 is removed. After the removal of the resist pattern 3, the seed layer 2 exposed in the regions 5 is removed by flash etching as shown in FIG. 1(e).

The flash etching according to this embodiment of the invention is implemented using a dip bath that can cool an etching liquid to 0° C. or less. The etching liquid is cooled preferably to about 15° C. or less, and more preferably to about 5° oC. to about 10° C. By performing the flash etching using a cooled etching liquid, the amount of the circuit pattern 4 that is etched can be reduced as compared with the conventional flash etching at room temperature (i.e. about 20° C.). This is in part due to employing the cooled etching liquid which suppresses the generation of hydrogen gas during the etching. Another factor is a potential difference that develops between the seed layer 2 and the circuit pattern 4 in the etching liquid can be increased as the etching liquid temperature is decreased. Hereinbelow, these reasons will be described in detail.

Upon dissolving copper when using an etching liquid, hydrogen gas is generated simultaneously with the dissolution of copper as shown by a reaction formula (1).

Cu→Cu²⁺+2e⁻, 2H⁺+2e⁻→H₂ (1)

When a large amount of hydrogen gas is generated during etching, the et ching is impeded by the generated hydrogen gas. Specifically, since hydrogen is generated on the seed layer 2, a contact area between the etching liquid and the seed layer 2 is reduced due to the presence of generated hydrogen. As a result, an etching time to achieve a breakpoint is increased. Particularly, inasmuch as a distance D (see FIG. 1(d)) between confronting portions of the circuit pattern 4 is shortened due to miniaturization of features on a printed circuit board in recent years, diffusion of hydrogen generated between the confronting portions of the circuit pattern 4 is impeded, and therefore, the etching time is increased. When the etching time is increased, the circuit pattern 4 is also etched. Hence, a shorter etching time is desirable.

When a cooled etching liquid is used, the rate of reaction between the etching liquid and copper is decreased. Thereby, the generation of the hydrogen gas is suppressed so that the seed layer 2 is more readily brought into contact with the etching liquid. Since a contact area between the seed layer 2 and the etching liquid per unit time is increased as compared with that in the conventional technique, the etching time and the breakpoint of the seed layer 2 are reduced as compared with those in the conventional technique. As a result, the amount of the circuit pattern 4 that is etched can be reduced.

As the distance D of the circuit pattern 4 decreases, hydrogen generated therein is more reluctant to diffuse out of regions 5 and remains therein. Therefore, an aspect of the invention becomes more pronounced in that the generation of the hydrogen gas is suppressed so that the seed layer 2 is more readily brought into contact with the etching liquid as described hereinabove. The distance D of the circuit pattern 4 is preferably 150 mm op less, and more preferably about 25 μm.

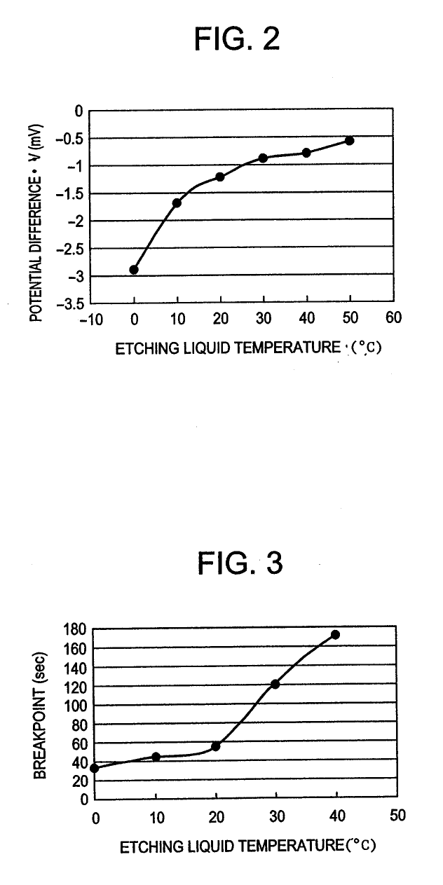

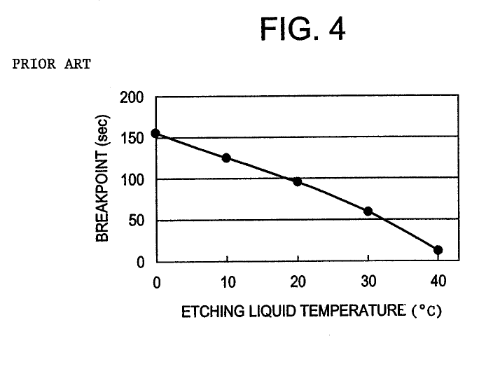

FIG. 2 shows a relationship between a potential difference caused between the seed layer 2 and the circuit pattern 4 in an etching liquid, and a temperature of the etching liquid. Here, 0.1N H₂SO₄ is used as the etching liquid. A potential difference DV is given by the following equation (2).

ΔV=Potential of Seed Layer−Potential of Circuit Pattern (2)

Referring to FIG. 2, the potential difference ΔV increases as the temperature of the etching liquid decreases. It is presumed that this is because the electrolytic copper plating layer forming the circuit pattern 4 is a more “noble” metal compared to the electroless copper plating layer forming the seed layer 2, and conversely, the electroless copper plating layer is a more “base” metal compared to the electrolytic copper plating layer. Particularly, the potential difference ΔV becomes large when the temperature of the etching liquid is about 15° C. or less. Therefore, as the temperature of the etching liquid decreases, the seed layer 2 becomes more susceptible to being etched. Conversely, as the temperature of the etching liquid decreases, the circuit pattern 4 becomes less susceptible to being etched due to cathode anti-corrosion. Further, since the breakpoint is reduced, the etching time can also be shortened. As a result, the amount of etching of the circuit pattern 4 can be reduced. Such an effect becomes significant particularly when the temperature of the etching liquid is about 15° C. or less.

In an embodiment of the invention, the etch time can be reduced, and therefore, the manufacturing time of the printed circuit board can be reduced. FIG. 3 shows a relationship between the temperature of the etching liquid and the breakpoint in the flash etching according to this embodiment. It is understood that the breakpoint is reduced as the temperature of the etching liquid is lowered.

In conventional flash etching, a spray type has been employed wherein a substrate is conveyed on a conveyor and etching is locally applied thereto using a spray. On the other hand, in a printed circuit board manufacturing method according to this embodiment, it is also possible to employ a dip type process that uses a carrier and a dip bath, for the purpose of controlling the quality of printed circuit boards. The employment of the dip type makes it possible to prevent the occurrence of cracks that would otherwise be caused upon conveying the substrate on the conveyor. Further, in the spray process, the etching depends on the dispersion of the spray which is incident upon the substrate. On the other hand, in the dip type, inasmuch as the substrate is dipped in an etching liquid within the dip bath, dispersion of the etch does not occur. Further, an etching device of the dip type is less expensive than that of the spray type. Although a carrying time of the substrate in the dip type is longer than that in the spray type, inasmuch as the etching time can be shortened according to this embodiment of the invention, the increase in the carrying time can be canceled.

Although copper plating is described in this embodiment of the invention, like effects can be achieved by plating of other metals.

The etching liquid may be an SPS aqueous solution, an H ₂O₂—H₂S^{O}4 aqueous solution, or any other as long as it is an acid etching liquid. As the concentration of the etching liquid decreases, the amount of etching of the circuit pattern 4 can be further reduced. However, when it is necessary to shorten the etching time by taking into account manufacturing process time, the concentration thereof may be set higher.

While embodiments of the invention have been described, it is to be understood that the spirit and scope of the invention is not limited thereby. Rather, various modifications may be made to embodiments of the invention without departing from the overall scope of the invention as described above and as set forth in the several claims appended hereto.

1. A method of forming a printed circuit board, the method comprising the steps of:
providing a substrate comprising a seed layer formed by electroless plating;
forming a masking layer on said seed layer to provide first regions of exposed seed layer;
forming a circuit pattern on said first regions of exposed seed layer by electrolytic plating;
removing said masking layer to expose second regions of said seed layer; and
etching said exposed second regions of said seed layer with an etching liquid, said etching liquid at a temperature less than about 15 degrees Celcius.

2. The method of claim 1, wherein the temperature of said etching liquid is about 5° C. to about 10° C.

3. The method of claim 1, wherein said masking layer comprises photoresist.

4. The method of claim 1, wherein said seed layer and said circuit pattern comprise copper.

5. The method of claim 1, wherein a distance between confronting portions of said circuit pattern is about 150 μm or less.

6. The method of claim 1, wherein said seed layer and said circuit pattern are formed by copper plating.

7. The method of claim 1, wherein said etching liquid comprises an acid.

8. The method of claim 7, wherein said acid comprises an H ₂O₂—H₂SO₄ aqueous solution.

9. The method of claim 1, wherein said substrate is dipped in said etching liquid within a dip bath.
